(19) United States
(12) Patent Application Publication
(10) Pub. No.: US 2013/0191586 A1
(43) Pub. Date: Jul. 25, 2013

(54) METHOD FOR OPERATING MEMORY CONTROLLER AND SYSTEM INCLUDING THE SAME

(71) Applicant: Samsung Electronics Co., Ltd., Suwon-si (KR)

(72) Inventor: Sang Jun Yang, Hwaseong-si (KR)

(73) Assignee: Samsung Electronics Co., Ltd., Suwon-si (KR)

(21) Appl. No.: 13/743,783

(22) Filed: Jan. 17, 2013

(30) Foreign Application Priority Data
Jan. 20, 2012 (KR) 10-2012-0006615

(51) Int. Cl. G06F 12/06; G11C 7/10

(52) U.S. Cl. CPC G06F 12/0607; G11C 7/1072
USPC 711/105; 711/157

(57) ABSTRACT

Methods of operating a memory controller include requesting data from each of a plurality of separate memory devices in response to an in-order multi-memory read request and then reading the requested data from the plurality of separate memory devices. The data read from the plurality of separate memory devices is then transmitted to a system bus along with at least one indication signal that identifies a relationship between an ordering of the requested data according to memory device and an ordering of the transmitted data according to memory device.

### REFERENCE TO PRIORITY APPLICATION

This application claims priority under 35 U.S.C. §119 from Korean Patent Application No. 10-2012-0006615, filed on Jan. 20, 2012, the disclosure of which is hereby incorporated herein by reference in its entirety.

### FIELD

This invention relates to methods for operating a memory controllers and systems including the same, and more particularly, to methods for preventing a data bottleneck phenomenon in memory controllers and systems including the same.

### BACKGROUND

A semiconductor memory device is mostly used as a memory medium of a main memory device. The semiconductor memory device has two kinds, a read only memory (ROM) and a random access memory (RAM). The ROM is a memory device which is only able to read, and recorded data are not erased even though a power supply is stopped. The ROM has various kinds such as a mask ROM, a programmable ROM (PROM), and an erasable programmable ROM (EPROM). Data recorded in the RAM may be changed by a user and the RAM may store a program or data. When a power supply is stopped, data recorded in the RAM are all erased. RAM has two kinds, a static RAM (SRAM) and a dynamic RAM(DRAM). The SRAM retains recorded data while a power is supplied, and the DRAM retains data only when the data are refreshed periodically. DRAM is generally used as a main memory device. Recently, as operations for performing several functions are processed in a system, demands for bandwidth of the system are growing. According to such a demand, the DRAM is used as a multi-channel and an interleaving method is used to utilize effectively a multi-channel DRAM system. The interleaving method is a method, by designating a successive address to a plurality of memories (e.g., a plurality of DRAMs) having the plurality of DRAMs recognized logically as a region. The interleaving method may increase bandwidth even without speeding up a processing speed of a memory.

### SUMMARY

An embodiment of the present invention is directed to an operation method of a memory controller for controlling a plurality of memories, including determining whether to read access each of at least two memories among the plurality of memories based on an in-order read request and generating a first indication signal according to a determination result, reading read-requested data from each of a plurality of read accessed memories in response to the in-order read request, and transmitting each read data and the first indication signal to a system bus.

According to an example embodiment, the memory controller may control the plurality of memories in an interleaving mode. According to an example embodiment, generating a second indication signal indicating an order of the read-requested data based on the in-order read request is further included, and the transmitting may transmit the each read data, the first indication signal and the second indication signal to the system bus.

According to an example embodiment, generating a third indication signal indicating whether reordering of the each read data is necessary based on the first indication signal and the second indication signal is further included, and the transmitting may transmit the each read data and the third indication signal to the system bus. According to an example embodiment, each of the plurality of memories may be a dynamic random access memory.

An example embodiment of the present inventive concepts is directed to an operation method of a system, which includes a memory controller for controlling a plurality of memories and a plurality of master IPs, including determining whether to read access each of at least two memories among the plurality of memories based on an in-order read request and generating a first indication signal according to a determination result, reading read requested data from each of a plurality of read accessed memories in response to the in-order read request, generating a second indication signal including information for an order of the read requested data based on the in-order read request, and determining whether reordering of the each read data is necessary based on the first indication signal and the second indication signal and reordering the each read data according to a determination result. The reordering may be performed in at least one of the plurality of master IPs.

According to an example embodiment, the memory controller may control the plurality of memories in an interleaving mode. According to an example embodiment, the generating the second indication signal may be performed in at least one of the plurality of master IPs. According to an example embodiment, the reordering may perform reordering by using a first-in first-out (FIFO) memory buffer. According to an example embodiment, each of the plurality of memories may be a dynamic random access memory.

### BRIEF DESCRIPTION OF THE DRAWINGS

The above and other features and advantages of the inventive subject matter will become more apparent by describing in detail exemplary embodiments thereof with reference to the attached drawings in which:

FIG. 1 is a block diagram of a data processing system according to an example embodiment of the present inventive concepts;

FIG. 2 is a block diagram of a system bus, a memory controller, a first memory and a second memory illustrated in FIG. 1;

FIG. 3 is a block diagram of a transaction queue illustrated in FIG. 2;

FIG. 4 is a block diagram of a master IP illustrated in FIG. 1;

FIG. 5 is a drawing for explaining a method for processing an in-order read request according to an example embodiment of the present inventive concepts;

FIG. 6 is a drawing for explaining a comparison example of the method for processing the in-order read request illustrated in FIG. 5;

FIG. 7 is a flowchart of an operation method of a memory controller according to an example embodiment of the present inventive concepts;

FIG. 8 is a flowchart of an operation method of the memory controller according to another example embodiment of the present inventive concepts;

FIG. 9 is a flow chart of an operation method of the memory controller according to still another example embodiment of the present inventive concepts;

FIG. 10 is a flowchart of an operation method of a system according to an example embodiment of the present inventive concepts;

FIG. 11 is a cross-sectional view of a die package including a master IP, a memory controller, a first memory and a second memory which are illustrated in FIG. 1;

FIG. 12 is a block diagram depicting an example embodiment of a system including the data processing system illustrated in FIG. 1;

FIG. 13 is a block diagram depicting another example embodiment of the system including the data processing system illustrated in FIG. 1;

FIG. 14 is a block diagram depicting still another example embodiment of the system including the data processing system illustrated in FIG. 1; and

FIG. 15 is a block diagram depicting still another example embodiment of the system including the data processing system illustrated in FIG. 1.

### DETAILED DESCRIPTION

The inventive subject matter now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

‘Module’ of the present inventive concepts may mean a functional or a structural combination of hardware for performing an method according to an example embodiment of the present inventive concepts or software which may drive the hardware. Accordingly, the module may mean a logical unit or set of a program code and hardware resource which may perform the program code.

A desirable example embodiment of the present inventive concepts is explained referring to attached drawings to explain the present inventive concepts in detail.

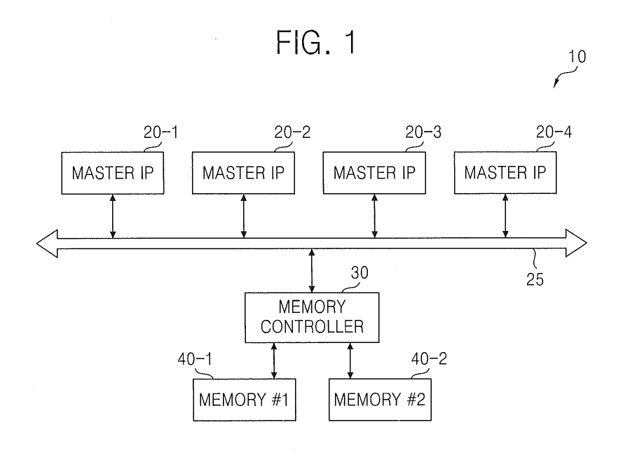

FIG. 1 is a block diagram of a data processing system according to an example embodiment of the present inventive concepts. Referring to FIG. 1, a data processing system 10 includes a plurality of master intellectual properties (IPs) 20-1 to 20-4, a system bus 25, a memory controller 30, a first memory 40-1 and a second memory 40-2. For convenience of explanation, FIG. 1 illustrates four master IPs 20-1 to 20-4 and two memories 40-1 and 40-2; however, the present concept is not restricted to the number of master IPs and the number of memories. According to an example embodiment, each of the plurality of master IPs 20-1 to 20-4 may be embodied in a central processing unit (CPU), a codec, a video scaler or an audio digital signal processing (audio DSP); however it is not restricted thereto. Each of the plurality of master IPs 20-1 to 20-4 may generate a read request for reading data stored in each of the plurality of memories 40-1 and 40-2.

According to an example embodiment, each of the plurality of master IPs 20-1 to 20-4 may generate an in-order read request for reading data stored in each of the plurality of memories 40-1 and 40-2 according to an order. The in-order read request may include information regarding a read command, an address, a size of data to read and/or an order of data to read.

The plurality of master IPs 20-1 to 20-4 and a memory controller 30 may communicate with each other through a system bus 25. The memory controller 30 may read data stored in each of the plurality of memories 40-1 and 40-2 based on a read request (e.g., an in-order read request) transmitted from each of the plurality of master IPs 20-1 to 20-4. According to an example embodiment, the memory controller 30 may control the plurality of memories 40-1 and 40-2 in an interleaving mode. Each of the plurality of memories 40-1 and 40-2 may store data which are necessary for each operation of the plurality of master IPs 20-1 to 20-4. According to an example embodiment, each of the plurality of memories 40-1 and 40-2 may be embodied in a volatile memory such as a dynamic random access memory (DRAM), a static random access memory (SRAM), a thyristor RAM (TRAM), a zero capacitor RAM (Z-RAM) or a twin transistor RAM (TTRAM). According to another example embodiment, each of the plurality of memories 40-1 and 40-2 may be embodied in a non-volatile memory such as an electrically erasable programmable read-only memory (EEPROM), a flash memory, a magnetic RAM (MRAM), a spin-transfer torque MRAM, a conductive bridging RAM (CBRAM), a ferroelectric RAM (FeRAM), a phase change RAM (PRAM), a resistive RAM (RRAM), a nanotube RRAM, a polymer RAM (PoRAM), a nano floating gate memory (NFGM), a holographic memory, a molecular electronics memory device or an insulator resistance change memory.

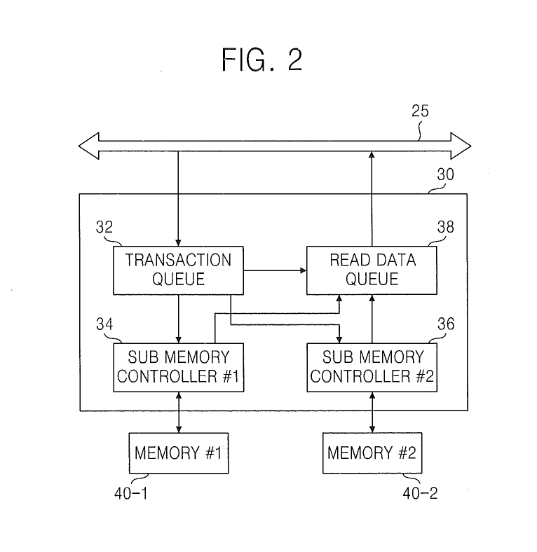

FIG. 2 is a block diagram of the system bus, the memory controller, the first memory and the second memory illustrated in FIG. 1. Referring to FIGS. 1 and 2, the memory controller 30 includes a transaction queue 32, a first sub memory controller 34, a second sub memory controller 36 and a read data queue 38. The transaction queue 32 may determine which memory to access based on a read request received from each of the plurality of master IPs 20-1 to 20-4 and get the first sub memory controller 34 and/or the second sub memory controller 36 to access each of the plurality of memories 40-1 and 40-2.

According to an example embodiment, the transaction queue 32 may determine whether to access more than two memories based on an in-order read request received from each of the plurality of master IPs 20-1 to 20-4 and generate a first indication signal according to a determination result. According to an example embodiment, the transaction queue 32 may generate a second indication signal indicating an order of data which are read-requested based on an in-order read request received from each of the plurality of master IPs 20-1 to 20-4. According to an example embodiment, the transaction queue 32 may transmit the first indication signal and/or the second indication signal to a read data queue 38.

The first sub memory controller 34 may access (e.g., read access) a first memory 40-1 according to a control of the transaction queue 32. In this case, the first sub memory controller 34 may transmit data read from the first memory 40-1 to the read data queue 38. The second sub memory controller 36 may access (e.g., read access) a second memory 40-2 according to a control of the transaction queue 32. In this case, the second sub memory controller 36 may transmit data read from the second memory 40-2 to the read data queue 38. The read data queue 38 may receive and buffer data, which are read from each of the plurality of memories 40-1 and 40-2, from the first sub memory controller 34 and/or the second sub memory controller 36, and output buffered data to the system bus 25.

According to an example embodiment, the read data queue 38 may output data read from each of the plurality of memories 40-1 and 40-2 and a first indication signal and/or a second indication signal transmitted from the transaction queue 32 to the system bus 25. According to an example embodiment, the read data queue 38 may generate a third indication signal indicating whether reordering of data which are read from each of the plurality of memories 40-1 is necessary based on the first indication signal and the second indication signal which are transmitted from the transaction queue 32. In this case, the read data queue 38 may output data, which are read from each of the plurality of memories 40-1 and 40-2, and the third indication signal to the system bus 25.

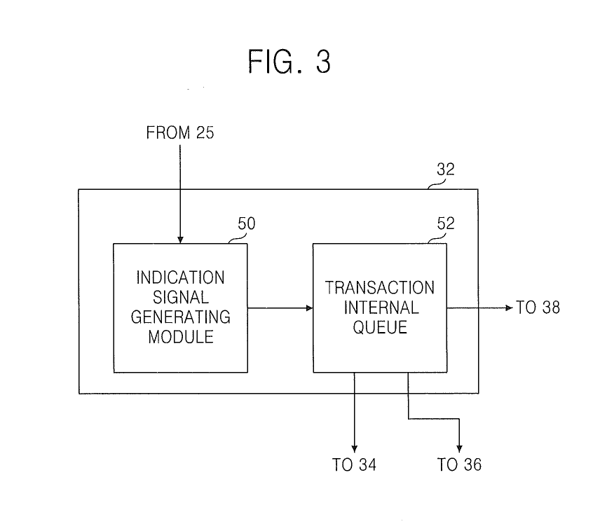

FIG. 3 is a block diagram of the transaction queue illustrated in FIG. 2. Referring to FIGS. 1 to 3, the transaction queue 32 includes an indication signal generating module 50 and a transaction internal queue 52. The indication signal generating module 50 may receive a read request (e.g., an in-order read request) from the plurality of master IPs 20-1 to 20-4 through the system bus 25. The indication signal generating module 50 may determine whether the memory controller 30 should access more than two memories based on a read request (e.g., an in-order read request) and generate a first indication signal according to a determination result.

According to an example embodiment, the indication signal generating module 50 may generate additionally a second indication signal indicating an order of data read requested based on a read request (e.g., an in-order read request). According to an example embodiment, the indication signal generating module 50 may transmit a read request (e.g., an in-order read request) and the first indication signal and/or the second indication signal to the transaction internal queue 52.

The transaction internal queue 52 may transmit a first indication signal and/or a second indication signal transmitted from the indication signal generating module 50 to the read data queue 38. The transaction internal queue 52 may determine which memory to access based on a read request (e.g., an in-order read request) transmitted from the indication signal generating module 50, and get the first sub memory controller 34 and/or the second sub memory controller 36 to access each of the plurality of memories 40-1 and 40-2 according to a determination result. For convenience of explanation, it is illustrated that the transaction internal queue 52 receives a read request (e.g. ,an in-order read request) from the indication signal generation module 50; however, the transaction internal queue 52 may receive a read request, e.g., an in-order read request, from the system bus 25 directly.

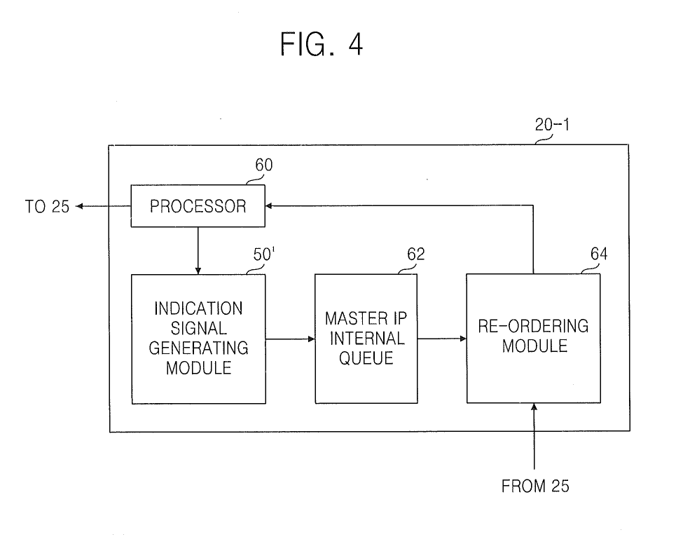

FIG. 4 is a block diagram of a mater IP illustrated in FIG. 1. Referring to FIGS. 1, 3 and 4, a master IP 20-1 includes a processor 60 and a reordering module 64. According to an example embodiment, the master IP 20-1 may further include an indication signal generating module 50′ and a master IP internal queue 62. For convenience of explanation, FIG. 4 illustrates a case of the master IP 20-1; however, other IPs 20-2 to 20-3 may have a structure substantially the same as the master IP 20-1, respectively. The indication signal generating module 50′ of FIG. 4 is substantially the same as the indication signal generating module 50 of FIG. 3 except for its layout and connection relation. The processor 60 may control a general operation of the master IP(20-1). According to an example embodiment, the processor 60 may transmit a read request (e.g., an in-order read request) to the indication signal generating module 50′. The indication signal generating module 50′ may generate a second indication signal indicating an order of data read requested based on a read request (e.g., an in-order read request).

According to an example embodiment, the master IP internal queue 62 may receive the second indication signal from the indication signal generating module 50′, buffer a received second indication signal and transmit a buffered second indication signal to a reordering module 64. The reordering module 64 may receive a first indication signal and data, which are read from each of the plurality of memories 40-1 and 40-2, from the system bus 25 and receive a second indication signal from the master IP internal queue 62. In this case, the reordering module 64 may determine whether reordering of data read from each of the memories 40-1 and 40-2 is necessary based on the first indication signal and the second indication signal, and perform a reordering operation according to a determination result.

According to an example embodiment, the reordering operation may be performed by using data first in first out (FIFO). According to an example embodiment, the reordering module 64 may receive the first indication signal, the second indication signal and data, which are read from each of the plurality of memories 40-1 and 40-2, from the system bus 25. In this case, the master IP 20-1 may not include the indication signal generating module 50′ and the master IP internal queue 62. According to another example embodiment, the reordering module 64 may receive a third indication signal and data, which are read from each of the plurality of memories 40-1 and 40-2, from the system bus 25. In this case, the master IP 20-1 may not include the indication signal generating module 50′ and the master IP internal queue 62. Additionally, the reordering module 64 may determine whether to perform a reordering operation according to the third indication signal.

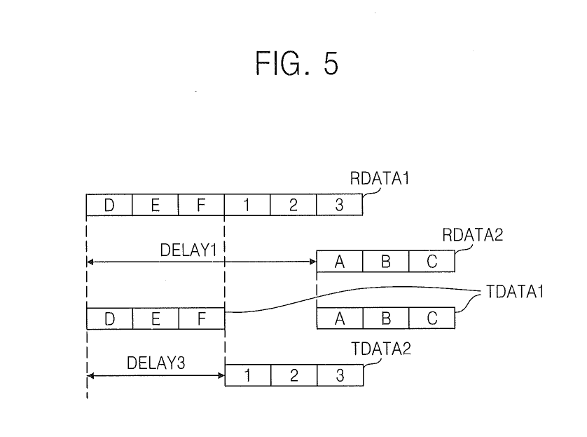

FIG. 5 is a drawing for explaining a method for processing an in-order read request according to an example embodiment of the present inventive concepts. For convenience of explanation, it is assumed that a master IP 20-1 makes an in-order read request on data A to F and a master IP 20-2 makes an in-order read request on data 1 to 3 in the followings. In addition, it is assumed that the in-order read request of the master IP 20-1 and the in-order read request of the master IP 20-2 are independent from each other.

Referring to FIGS. 1, 2 and 5, first read data RDATA1 are data read from a first memory 40-1 and second read data RDATA2 are data read from a second memory 40-2. First transmission data TDATA1 are data transmitted from the read data queue 38 to the master IP 20-1 through the system bus 25 and second transmission data TDATA2 are data transmitted from the read data queue 38 to the master IP 20-2 through the system bus 25. According to an example embodiment, each of the first transmission TDATA1 and the second transmission data TDATA2 may be transmitted from the read data queue 38 to the system bus 25 through different data paths. A delay DELAY1 indicates an unintentional delay occurred during a read operation according to a property of the second memory 40-2, and a delay DELAY3 indicates a delay from when the master IP 20-2 makes an in-order read request to when the second transmission data TDATA2 are transmitted from the read data queue 38 to the system bus 25. The data A to F in FIG. 5 should be read successively. However, data A to C are read later than data D to F due to a delay DELAY1.

The memory controller 30 does not perform reordering of data A to F and data 1 to 3 in the method for processing an in-order read request according to an example embodiment of the present inventive concepts. For example, the memory controller 30 may not store data D to F and data 1 to 3 in the read data queue 38 until data A to C are read. In this case, the data D to F may be transmitted first to a master IP 20-1 through the system bus 25 along with a first indication signal and/or a second indication signal generated in the transaction queue 32, and the data A to C read later may be transmitted to the master IP 20-1 through the system bus 25.

The data 1 to 3 along with a first indication signal and/or a second indication signal may be transmitted to a master IP 20-2 through the system bus 25. According to an example embodiment, the data D to F may be first transmitted to the master IP 20-1 through the system bus 25, and a first indication signal and/or a second indication signal generated in the transaction queue 32 may be transmitted to the master IP 20-1 through the system bus 25 along with data A to C read later. According to another example embodiment, the data D to F may be transmitted to the master IP 20-1 through the system bus 25 along with a first indication signal and/or a second indication signal generated in the transaction queue 32, and the data A to C read later may be transmitted to the master IP 20-1 along with the first indication signal and/or the second indication signal through the system bus 25.

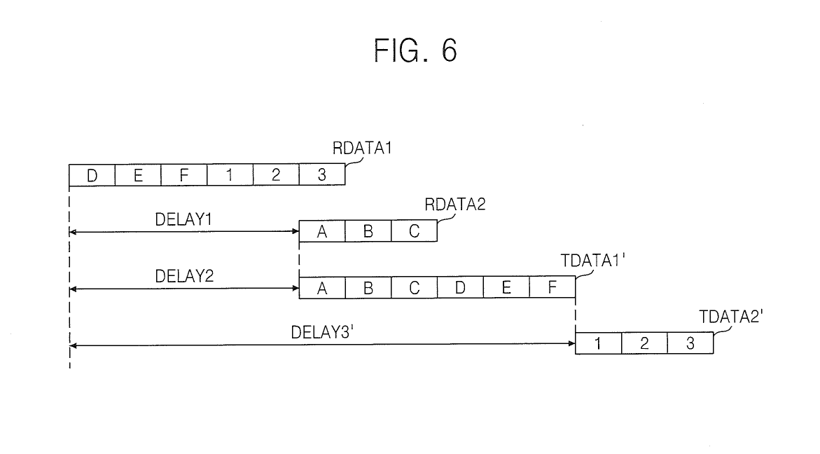

FIG. 6 is a drawing for explaining a comparison example of the method for processing an in-order read request illustrated in FIG. 5. Referring to FIGS. 1, 2, 5 and 6, FIG. 6 is a comparison example against the method for processing an in-order reading request according to an example embodiment of the present inventive concepts. and there is depicted a method for processing an in-order read request when the memory controller 30 perform reordering. Data A to F in FIG. 6 should be read successively. However, data A to C are read later than data D to F due to a delay DELAY1. When the memory controller 30 performs reordering of the data A to F and data 1 to 3, the data D to F are read earlier than the data A to C. However, the data D to F should be stored in the read data queue 38 for reordering until the data A to C are read. Because of this, a whole first transmission data TDATA1′ has a delay DELAY2. In addition, the data 1 to 3 may have a longer delay DELAY3′ than the delay DELAY3 in the method for processing an in-order read request according to an example embodiment of the present inventive concepts. When comparing the method for processing an in-order read request according to an example embodiment of the present inventive concepts in FIG. 5 with the comparison example of FIG. 6, the method for processing an in-order read request of the present inventive concepts may reduce a delay of the data D to F and a delay of the data 1 to 3.

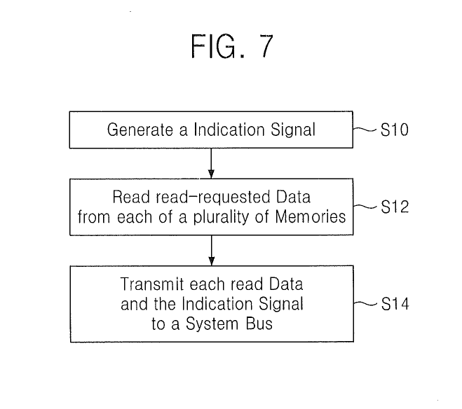

FIG. 7 is a flowchart of an operation method of a memory controller according to an example embodiment of the present inventive concepts. Referring to FIGS. 1, 2, 3 and 7, the indication signal generating module 50 included in the transaction queue 32 may determine whether to access more than two memories based on an in-order read request received from the plurality of master IPs 20-1 to 20-4 and generate a indication signal (e.g., a first indication signal) according to a determination result (S10). The memory controller 30 may read data stored in each of a plurality of memories 40-1 and 40-2 based on a read request transmitted from each of the plurality of master IPs 20-1 to 20-4(S12). The memory controller 30 may transmit each read data and the indication signal (e.g., a first indication signal) to the system bus 25 (S14).

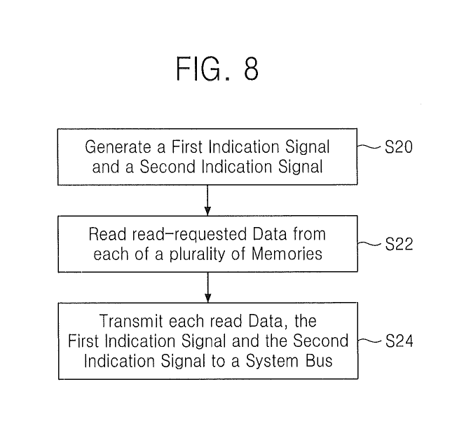

FIG. 8 is a flowchart of an operation method of the memory controller according to another example embodiment of the present inventive concepts. Referring to FIGS. 1, 2, 3 and 8, the indication signal generating module 50 included in the transaction queue 32 may determine whether to access more than two memories based on a read request (e.g., an in-order read request) and generate a first indication signal according to a determination result (S20). The indication signal generating module 50 included in the transaction queue 32 may generate additionally a second indication signal indicating an order of data read requested based on a read request (e.g., an in-order read request (S20)). The memory controller 30 may read data stored in each of the plurality of memories 40-1 and 40-2 based on a read request transmitted from each of the plurality of master IPs 20-1 to 20-4 (S22). The memory controller 30 may transmit each read data, a first indication signal and a second indication signal to the system bus 25(S24).

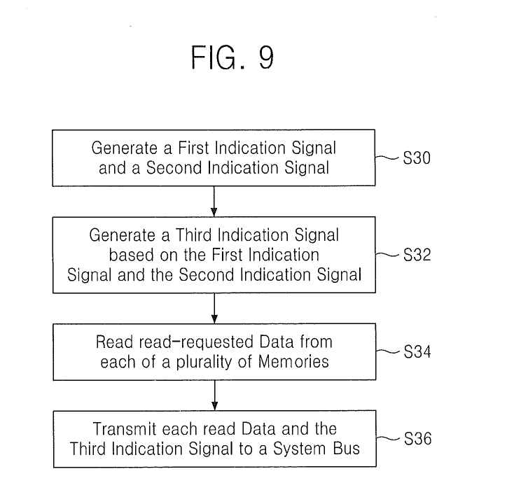

FIG. 9 is a flowchart of an operation method of the memory controller according to still another example embodiment of the present inventive concepts. Referring to FIGS. 1, 2, 3, 8 and 9, steps S30 and S34 are substantially the same as steps S20 and S22 of FIG. 8, respectively, so that explanation for them is omitted. The read data queue 38 included in the memory controller 30 may generate a third indication signal indicating whether reordering of data read from a plurality of memories 40-1 and 40-2 is necessary based on a first indication signal and a second indication signal (S32). The memory controller 30 may transmit each read data and a third indication signal to the system bus 25(S36).

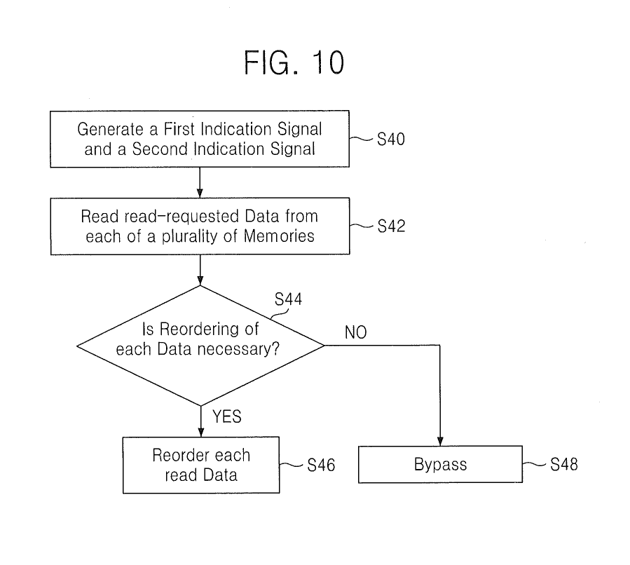

FIG. 10 is a flowchart of an operation method of a system according to an example embodiment of the present inventive concept. Referring to FIGS. 1 to 4, 8 and 10, steps S40 and S42 are substantially the same as steps S20 and S22 of FIG. 8, respectively, so that explanation for them is omitted. A reordering module 64 included in a master IP 20-1 may determine whether reordering of data read from each of the plurality of memories 40-1 and 40-2 is necessary based on a first indication signal and a second indication signal (S44). For example, when the memory controller 30 should access one memory, reordering of each read data may be determined to be unnecessary based on a first indication signal indicating whether the memory controller 30 should access more than two memories. For example, when the memory controller 30 should access more than two memories and an order of read requested data is the same as an order of each read data, reordering of the each read data may be determined to be unnecessary based on the first indication signal and a second indication signal indicating an order of read requested data. For example, when the memory controller 30 should access more than two memories and an order of read requested data is different from an order of each read data, reordering of the each read data may be determined to be necessary based on the first indication signal and the second indication signal.

The reordering module 64 included in a master IP 20-1 may perform a reordering operation of each read data when reordering is necessary according to a determination result (S46). The reordering module 64 included in the master IP 20-1 may bypass each read data to a processor 60 without performing a reordering operation of each read data when reordering is unnecessary according to the determination result (S48).

According to an example embodiment, a second indication signal may be generated in the indication signal generating module 50′ included in a master IP (e.g., 20-1). According to an example embodiment, the master IP (e.g., 20-1) may receive a third indication signal, which indicates whether reordering of read data is necessary, and each read data from the memory controller 30, and the reordering module 64 may perform a reordering operation according to the third indication signal. For example, when a logic level of the third indication signal is high, the reordering module 64 performs a reordering operation, and the reordering module 64 may not perform the reordering operation when a logic level of the third indication signal is low. According to an example embodiment, the reordering operation may be performed by using a first-in first-out (FIFO) memory device.

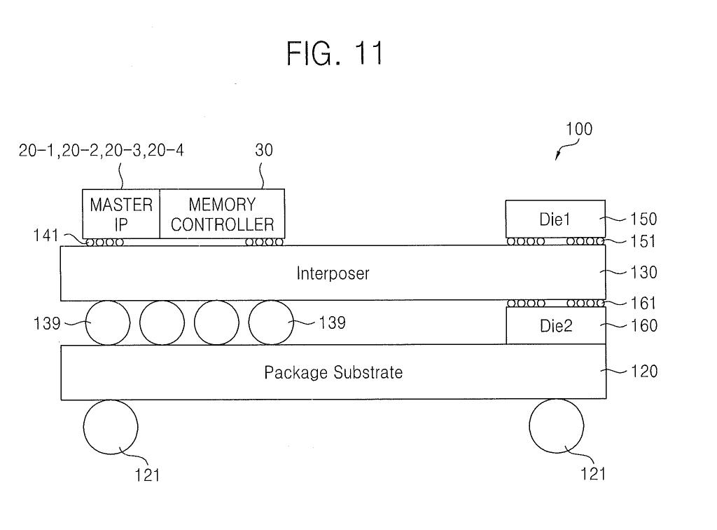

FIG. 11 is a cross-sectional view of a die package including a master IP, a memory controller, a first memory and a second memory which are illustrated in FIG. 1. Referring to FIGS. 1 and 11, a die package 100 includes the plurality of master IPs 20-1 to 20-4, the memory controller 30, a package substrate 120, a plurality of solder balls 121, an interposer 130, a plurality of bumps 139, a plurality of micro jumps 141, a first die 150, a first micro bumps 151, a second die 160 and a second micro bumps 161. According to an example embodiment, the package substrate 120 may be also called a printed circuit board (PCB). The plurality of solder balls 121 may be used to connect the package substrate 120 to a system board (not shown) or an external device. The interposer 130 may be mounted on the package substrate 120. The plurality of bumps 139 may be used to connect the interposer 130 to the package substrate 120. According to an example embodiment, the interposer 130 may be also called a silicon interposer. The plurality of master IPs 20-1 to 20-4, the memory controller 30 and the first die 150 may be mounted on the interposer 130.

For convenience of explanation, it is illustrated that the plurality of master IPs 20-1 to 20-4 and the memory controller 30 are mounted together on the interposer 130; however, each of the plurality of master IPs 20-1 to 20-4 and the memory controller 30 may be mounted separately on the interposer 130 according to an example embodiment. For convenience of explanation, it is illustrated that four master IPs 20-1 to 20-4 are mounted on the interposer 130, respectively; however, the number of master IPs may be changed. Each of the plurality of master IPs 20-1 to 20-4 and the memory controller 30 may be connected to the interposer 130 through the plurality of micro bumps 141.

According to an example embodiment, each of the plurality of master IPs 20-1 to 20-4 may be a central processing unit (CPU) performing commands of a program. According to an example embodiment, each of the plurality of master IPs 20-1 to 20-4 may be a graphic processing unit (GPU) accelerating image data for outputting a display(not shown). Each of the first die 150 and the second die 160 may be connected to the interposer 130 through each of the first micro bumps 151 and the second micro bumps 161. The second die 160 may be connected between the package substrate 120 and the interposer 130. The first die 150 and the second die 160 may be embodied in-line. Each of the first die 150 and the second die 160 may be also called a chip or an integrated circuit (IC). According to an example embodiment, each of the first die 150 and the second die 160 may be the first memory 40-1 or the second memory 40-2. Each of the plurality of master IPs 20-1 to 20-4 may perform other commands, e.g., an arithmetic command, by reading data output from the first die 150 or the second die 160. According to an example embodiment, a die package 100 may not include the plurality of master IPs 20-1 to 20-4, but include only the memory controller 30.

According to an example embodiment, each of the first die 150 and the second die 160 may be a volatile memory device such as a dynamic random access memory (DRAM), a static random access memory (SRAM), a thyristor RAM (TRAM), a zero capacitor RAM (Z-RAM) or a Twin Transistor RAM (TTRAM). According to another example embodiment, each of the first die 150 and the second die 160 may be a non-volatile memory device such as an electrically erasable programmable read-only memory (EEPROM), a flash memory, a magnetic RAM (MRAM), a spin-transfer torque MRAM, a conductive bridging RAM (CBRAM), a ferroelectric RAM (FeRAM), a phase change RAM (PRAM), a resistive RAM (RRAM), a nanotube RRAM, a polymer RAM (PoRAM), a nano floating gate memory (NFGM), a holographic memory, a molecular electronics memory device or an insulator resistance change memory.

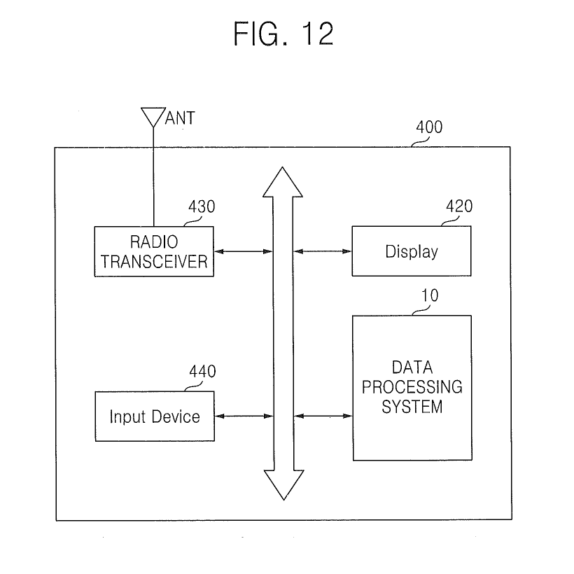

FIG. 12 is a block diagram depicting an example embodiment of a system including the data processing system illustrated in FIG. 1. Referring to FIGS. 1, 11 and 12, a system 400 may be embodied in a portable device such as a cellular phone, a smart phone or a tablet PC. The system 400 includes a data processing system 10, a display 420, a radio transceiver 430 and an input device 440. According to an example embodiment, the data processing system 10 may be embodied in the die package 100, and the die package 100 may be mounted on a system board (not shown) in this case. The display 420 may display data stored in the first memory 40-1 or the second memory 40-2 according to a control of each of the plurality of master IPs 20-1 to 20-4. The radio transceiver 430 may transmit or receive a radio signal through an antenna ANT. For example, the radio transceiver 430 may convert a radio signal received through the antenna ANT into a signal which may be processed by each of the plurality of master IPs 20-1 to 20-4. The radio transceiver 430 may convert a signal output from each of the plurality of mater IPs 20-1 to 20-4 into a radio signal and output a converted radio signal to outside through the antenna ANT. An input device 440 may be embodied in a device which may input a control signal for controlling an operation of each of the plurality of master IPs 20-1 to 20-4 or data to be processed by each of the plurality of master IPs 20-1 to 20-4, e.g., a pointing device such as a touch pad and a computer mouse, a keypad or a keyboard.

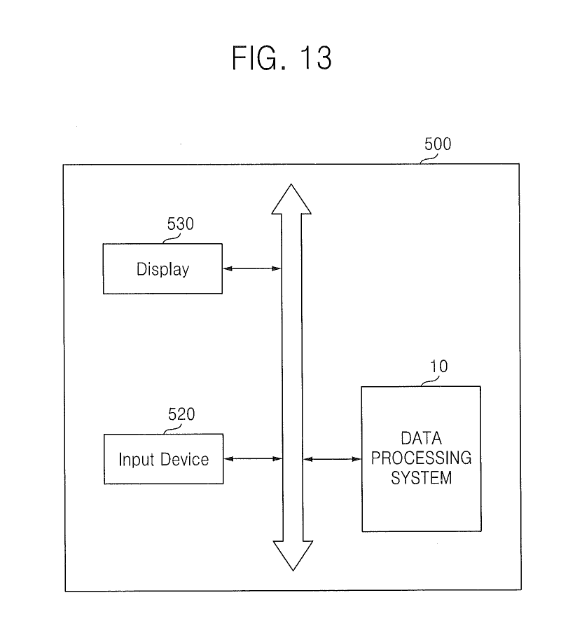

FIG. 13 is a block diagram depicting another example embodiment of the system including the data processing system illustrated in FIG. 1. Referring to FIGS. 11 and 13, a system 500 may be embodied in a personal computer (PC), a tablet PC, a net-book, an e-reader, a personal digital assistant (PDA), a portable multimedia player (PMP), a MP3 player or a MP4 player. The system 500 includes a data processing system 10 for controlling a general operation of the system 500, an input device 520 and a display 530. According to an example embodiment, the data processing system may be embodied in the die package 100, and in this case the die package 100 may be mounted on a system board (not shown). According to an example embodiment, the input device 520 may be embodied in a pointing device such as a touch pad or a computer mouse, a keypad or a keyboard. The display 530 may display data stored in the first memory 40-1 and/or the second memory 40-2 according to an input signal generated by the input device 520 under a control of each of the plurality of master IPs 20-1 to 20-4 included in the die package 100.

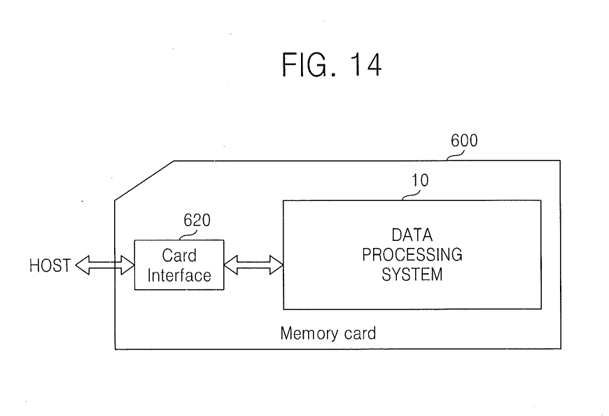

FIG. 14 is a block diagram depicting still another example embodiment of the system including the data processing system illustrated in FIG. 1. Referring to FIGS. 11 and 14, a system 600 may be embodied in a memory card or a smart card. The system 600 includes the data processing system 10 and a card interface 620. The data processing system 10 included in the system 600 may not include the plurality of master IPs 20-1 to 20-4. According to an example embodiment, the data processing system 10 may be embodied in the die package 100, and the die package 100 may be mounted on a system board(not shown) in this case. The memory controller 30 included in the data processing system 10 may control data exchange between the first memory 40-1 and/or the second memory 40-2 and the card interface 620. According to an example embodiment, the card interface 620 may be a secure digital (SD) card interface or a multi-media card(MMC) interface; however, it is not restricted thereto. The card interface 620 may interface data exchange between a host and the first memory 40-1 and/or the second memory 40-2 included in the data processing system 10 according to a protocol of a host. The system 600 may be connected to a host such as a computer, a digital camera, a digital audio player, a cellular phone, console video game hardware, or a digital set-top box.

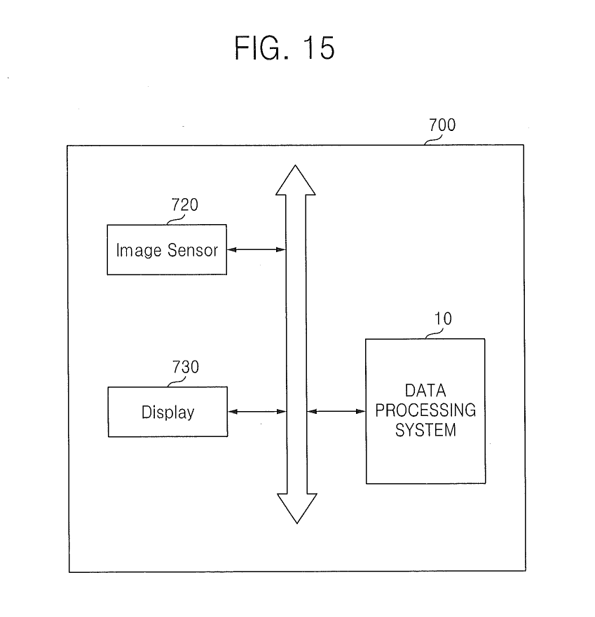

FIG. 15 is a block diagram depicting still another example embodiment of the system including the data processing system illustrated in FIG. 1. Referring to FIGS. 11 and 15, a system 700 may be embodied in a digital camera or a portable device equipped with a digital camera. The system 700 includes the data processing system 10 controlling a general operation of the system 700, an image sensor 720 and a display 730. According to an example embodiment, the data processing system 10 may be embodied in a die package 710, and the die package 710 may be mounted on a system board (not shown) in this case. The image sensor 720 may convert an optical image into a digital signal. A converted digital signal may be stored in the first memory 40-1 and/or the second memory 40-2 or displayed through the display 730 under a control of each of the plurality of master IPs 20-1 to 20-4 included in the data processing system 10. In addition, a digital signal stored in the first memory 40-1 and/or the second memory 40-2 may be displayed through the display 730 under a control of each of the plurality of master IPs 20-1 to 20-4.

Methods according to an example embodiment of the present inventive concepts may prevent a data bottleneck phenomenon of a memory controller by reordering each data read according to an in-order read request in a master IP.

While the inventive subject matter has been particularly shown and described with reference to exemplary embodiments thereof, it will be understood by those of ordinary skill in the art that various changes in forms and details may be made therein without departing from the spirit and scope of the inventive subject matter as defined by the following claims.

What is claimed is:

1. A method of operating a memory controller, comprising:
requesting data from each of a plurality of separate memory devices in response to an in-order multi-memory read request;
reading the requested data from the plurality of separate memory devices; and
transmitting the data read from the plurality of separate memory devices to a system bus along with a first indication signal that indicates the transmitted data as read data responsive to the in-order multi-memory read request.

2. The method of claim 1, wherein said transmitting comprises transmitting a second indication signal to the system bus that indicates an ordering of the requested data according to memory device.

3. The method of claim 2, wherein said transmitting comprises transmitting a third indication signal to the system bus that indicates whether an ordering of the transmitted data according to memory device is equivalent to the ordering of the requested data according to memory device.

4. A method of operating a memory controller for controlling a plurality of memories, the method comprising:
determining whether to read access each of at least two memories among the plurality of memories based on an in-order read request and generating a first indication signal according to a determination result;
reading read-requested data from each of read accessed memories in response to the in-order read request; and
transmitting each read data and the first indication signal to a system bus.

5. The method of claim 4, wherein the memory controller controls the plurality of memories in an interleaving mode.

6. The method of claim 4, further comprising generating a second indication signal indicating an order of the read requested data based on the in-order read request,
wherein the transmitting transmits the each read data, the first indication signal and the second indication signal to the system bus.

7. The method of claim 6, further comprising generating a third indication signal indicating whether reordering of the each read data is necessary based on the first indication signal and the second indication signal,
wherein the transmitting transmits the each read data and the third indication signal to the system bus.

8. The method of claim 4, wherein each of the plurality of memories is a dynamic random access memory.

9. A method of operating a system including a memory controller for controlling a plurality of memories and a plurality of master intellectual properties (IPs), the method comprising:
determining whether to read access each of at least two memories among the plurality of memories based on an in-order read request and generating a first indication signal according to a determination result;
generating a second indication signal including information regarding an order of the read requested data based on the in-order read request;
reading read requested data from each of read accessed memories in response to the in-order read request; and
determining whether reordering of each read data is necessary based on the first indication signal and the second indication signal and reordering the each read data according to a determination result,
wherein the reordering is performed in at least one of the plurality of master IPs.

10. The method of claim 9, wherein the memory controller controls the plurality of memories in an interleaving mode.

11. The method of claim 9, wherein the generating the second indication signal is performed in at least one of the plurality of master IPs.

12. The method of claim 9, wherein the reordering reorders each read data by using data first in first out.

13. The method of claim 9, wherein each of the plurality of memories is a dynamic random access memory.
